(19) United States
(12) Patent Application Publication
(10) Pub. No.: US 2017/0146607 A1
(43) Pub. Date: May 25, 2017

(54) METHOD FOR DETERMINING CHARACTERISTIC OPERATING POINTS OF A BATTERY FROM INITIAL OPERATING POINTS ASSOCIATED WITH A CALIBRATION UNIT CELL INTENDED FOR BEING PROVIDED IN SAID BATTERY

(71) Applicant: COMMISSARIAT A L'ENERGIE ATOMIQUE ET AUX ENERGIES ALTERNATIVES, Paris (FR)

(72) Inventors: Kelli Mamadou, Fort de France (FR); Ayman Al Rahal Al Orabi, Chambéry (FR)

(73) Assignee: COMMISSARIAT A L'ENERGIE ATOMIQUE ET AUX ENERGIES ALTERNATIVES, Paris (FR)

(21) Appl. No.: 15/321,050

(22) PCT Filed: Jun. 24, 2015
(86) PCT No.: PCT/EP2015/064292

§ 371 Date: Dec. 21, 2016

(30) Foreign Application Priority Data
Jun. 26, 2014 (FR) 1455980

(51) Int. Cl. G01R 31/36

(52) U.S. Cl. CPC G01R 31/3641; G01R 31/3651; G01R 31/3658

(57) ABSTRACT

The method for determining a set of characteristic operating points defining the energy behavior of a predetermined battery equipped with a plurality of unit
includes (E1) determining a set of initial operating points associated with a calibration unit cell of the type intended to make up the predetermined battery and representative of the energy behavior of the calibration unit
cell; (E2) determining a set of intermediate operating points forming a subset of the set of initial operating;
points; and (E3) determining the set of characteristic operating points through implementing tests carried out on at least one calibration battery representative of the predetermined battery, each test determining a characteristic operating point by using data arising from one of said intermediate operating points.

### TECHNICAL FIELD OF THE INVENTION

The invention relates to the field of batteries.

More particularly, a subject of the invention is a method allowing a battery to be characterized on the basis of data arising from a unit cell of the type with which the battery is equipped.

### PRIOR ART

It is known practice to characterize a battery cell by making use of power data, remaining-energy data and energy state data. Within this context, document WO2011/000872 by the applicant describes a calibration method allowing such a characterization.

The energy state indicator may be used in the context of a tracking algorithm for the purpose of estimating and forecasting the available energy of a battery under a variety of operating conditions (stress regimes and temperatures). This indicator is designed for unit storage elements, typically a battery cell.

Depending on the desired application, the battery will comprise one or more cells adapting said battery in terms of power and voltage levels. The assembly of cells leads to changes in the electrical, thermal and, ultimately, energy behaviors of the batteries.

Methods for characterizing energy performance levels carried out on cells may, in the same way, be reproduced on a battery. However, they require the use of multiple batteries which will not be able to be placed back on the production line upon completion of the tests due to being overly degraded by these numerous tests.

One battery might comprise tens, hundreds or even thousands of unit cells. It is understood then that the tests usually carried out on a cell are very costly when they are carried out on a battery.

It is necessary to adopt characterization methods allowing, on the one hand, the number of test batteries to be drastically decreased and, on the other hand, the initial levels of performance of a battery to be retained after the characterization tests so that they remain marketable.

### OBJECT OF THE INVENTION

The aim of the present invention is to propose a solution that overcomes all or some of the drawbacks listed above.

This aim is addressed by virtue of a method for determining a set of characteristic operating points defining the energy behavior of a predetermined battery equipped with a plurality of unit cells, said method comprising the following steps:
determining a set of initial operating points associated with a calibration unit cell of the type of those intended to make up said predetermined battery and being representative of the energy behavior of the calibration unit cell;
determining a set of intermediate operating points forming a subset of the set of initial operating points;
determining said set of characteristic operating points through implementing tests carried out on at least one calibration battery representative of said predetermined battery, each test determining a characteristic operating point by using data arising from one of said intermediate operating points.

Preferably, each of the characteristic operating points is defined by at least one value of an energy state of the predetermined battery, one power value of the predetermined battery and one remaining-energy value of the predetermined battery, and each of the initial operating points and each of the intermediate operating points is defined by at least one value of an energy state of the calibration unit cell, one power value of the calibration unit cell and one remaining-energy value of the calibration unit cell.

According to one particular implementation, the step of determining the set of intermediate operating points comprises at least one cycle of the following steps:
choosing at least one set of potential intermediate operating points from among the set of initial operating points;
establishing, for each set of potential intermediate operating points, a corresponding surface, preferably established using Delaunay triangulation;
comparing each established surface with all or some of the initial operating points;
validating the choice of said at least one set of potential intermediate operating points depending on the result of said comparison.

Advantageously, for each established surface:
the comparison step comprises, on the one hand, for each initial operating point used in the comparison step, forming a pair of points comprising said initial operating point and a point of said established surface for which the energy state values of the calibration unit cell and the power values of the calibration unit cell are identical to those of said initial operating point and comprises, on the other hand, for each pair of points, determining a difference between the remaining-energy values of said initial operating point and of said point of said established surface;
the validation step comprises validating said at least one chosen set of potential intermediate operating points if, for each pair of points, said difference, or a value representative of the difference, is lower than a threshold.

According to one embodiment, the method may comprise choosing multiple sets of potential intermediate operating points from among the set of initial operating points, and multiple sets of potential intermediate operating points may be validated during the implementation of said validation step, in which case the method may furthermore comprise a step of selecting a single set of intermediate operating points from among said multiple validated sets of intermediate operating points.

Said selection step may comprise establishing, for each of the established surfaces associated with the validated sets of potential intermediate operating points, an average value of the difference determined between the remaining-energy values of the points of each pair associated with said established surface, the selected set of intermediate operating points corresponding to that associated with the established surface for which the value of the average is lowest.

Advantageously, the method comprises a first, initialization step in which four end operating points chosen from among the set of initial operating points are fixed, the remaining initial operating points forming a set of internal operating points, and a second step comprising the following steps:
defining a variable Nbₚₒᵢₙₜ representative of a number of operating points of the set of internal operating points to be used;
implementing said cycle of steps in which:
   all possible combinations of Nbₚₒᵢₙₜ points from among the total number of points of the set of internal operating points are determined;
   the choice step is such that each chosen set of potential intermediate operating points comprises the four fixed end points and one of the possible combinations.

According to one embodiment, the method may comprise a first iteration of the second step for which the value of Nbₚₒᵢₙₜ is 1, and a second iteration of the second step for which the value of Nbₚₒᵢₙₜ is 2 if no set of potential intermediate points is validated during the implementation of the cycle of steps associated with the first iteration of the second step.

Furthermore, according to a refinement, if, after j iterations of the second step, j preferably being equal to 2, no set of potential intermediate operating points has been validated, the method comprises a third step comprising the following steps:
incrementing Nbₚₒᵢₙₜ and randomly forming sets of Nbₚₒᵢₙₜ points, preferably distinct, chosen from among the points of the set of internal operating points until the number of sets of Nbₚₒᵢₙₜ points is equal to a predetermined threshold that is lower than the number of possible combinations of Nbₚₒᵢₙₜ points from among the total number of points of the set of internal operating points;
determining a plurality of surfaces, in particular from the Delaunay triangulation, each of the surfaces of the plurality of surfaces being defined on the basis of the four fixed end points and of one of the randomly formed sets of Nbₚₒᵢₙₜ points;
comparing each of the surfaces of the plurality of surfaces with the operating points of the set of initial points;
defining the points having been used to define a surface of the plurality of surfaces as a validated set of intermediate operating points if said step of comparing said surface satisfies an optimization condition, or else carrying out a new third step, preferably while Nbₚₒᵢₙₜ is smaller than or equal to 6.

Preferably, each implementation of a test consists of carrying out a step of discharging the calibration battery starting from a known energy state and a known discharge power which are determined on the basis of one of the points of the set of determined intermediate points, of measuring a corresponding amount of remaining energy, and of forming the characteristic operating point through association of the known energy state, the known discharge power and the measured remaining energy.

The invention also relates to a method for characterizing a predetermined battery equipped with a plurality of unit cells for a plurality of temperatures, said method comprising, for each temperature, an implementation of the method for determining a set of characteristic operating points defining the energy behavior of the predetermined battery such as described, and a step of associating said temperature with said set of characteristic operating points.

### BRIEF DESCRIPTION OF THE DRAWINGS

Other advantages and features will become more clearly apparent from the following description of particular embodiments of the invention, given by way of non-limiting examples and shown in the appended drawings, in which:

FIG. 1 illustrates a diagram of a determination method according to one embodiment of the invention;

FIG. 2 shows a table presenting the available energy as a function of the energy state and of the power at a predetermined temperature;

FIG. 3 shows a surface of the available remaining energy in a battery as a function of the energy state of the battery and of the power of the battery;

FIG. 4 illustrates one particular embodiment of step E2 in FIG. 1;

FIG. 5 illustrates one particular embodiment of the method according to the invention;

FIG. 6 illustrates two curves presenting the variation in the energy state of a battery as a function of time with and without the invention in order to prove the usefulness of the determination method.

### DESCRIPTION OF PREFERRED EMBODIMENTS OF THE INVENTION

The method described below differs from the prior art in that it aims to determine, from among a set of initial operating points characterizing a unit cell, a subset that is representative of the energy behavior of the unit cell. By definition, the subset comprises a number of operating points that is smaller than the number of points of the set of initial operating points. A battery including a plurality of unit cells is then tested by using the points of said subset, and preferably only said points of said subset. This results in the number of tests being minimized, and hence the number of batteries to be scrapped after the tests being limited, or even zero.

Stated otherwise, it is sought to minimize the number of tests to be carried out on a battery by depending on information collected on a unit cell of the type with which the battery is equipped. In concrete terms, it is sought to determine, before testing one or more batteries, which of those points of the energy surface of a battery should be characteristic of its energy behavior.

Before detailing the steps of one embodiment of the invention, it is necessary to provide some definitions.

A battery is a set of electrical accumulators connected to one another so as to create an electrical generator of the desired voltage and desired capacity. Throughout the present description, an electrical accumulator is also referred to as a unit cell. The unit cells of one and the same battery are preferably identical. Furthermore, a unit cell may comprise one or more energy storage elements connected to one another.

An energy state, termed “state of energy” (SOE), is defined as the ratio between the remaining energy E_{d/PN} available in a unit cell at time t under the assumption of an energy discharge under the nominal conditions of the unit cell, and the nominal total energy E_{Nom}, hence defined by the formula SOE=E_{d/PN} E_{Nom}. This value of SOE is between 0 and 1, the value equal to 1 corresponding to a fully charged energy state of the unit cell and the value equal to 0 to a fully discharged state. This value may also be expressed as a percentage varying between 0% and 100%.

The power P is located within an operating power range recommended by the manufacturer of the unit cell, either directly provided by this manufacturer, or deduced, for example from a current range provided by this manufacturer multiplied by a nominal supply voltage. This power depends on the state of use of the unit cell, namely charging or discharging. In the case of discharging, it will be said that the power P is drawn from the unit cell, and in the case of charging, it will be said that the power P is delivered to the unit cell. The power P that is available at time t may depend on the energy state, on the temperature and on the state of aging of the battery.

The charged and discharged states are determined according to the technology of the unit cell. They may be obtained from the recommendations of the maker of the accumulator (or of the battery), and generally from threshold voltages.

The remaining energy En corresponds to the useful energy of the unit cell; it is expressed in Wh, and accounts for the internal energy actually stored in the unit cell, and the energy lost through Joule heating via the internal resistance of the unit cell. Thus:

En=Ei−Ep

### Where

Ep=∫r·I²·dt: representing the energy lost through Joule heating via the internal resistance of the unit cell, and
Ei=Q·U: is the internal energy stored in the unit cell.

Stated otherwise, the remaining energy may correspond to the energy that the unit cell could effectively yield depending on its current conditions of use.

Although the concepts of energy state, power and remaining energy have been defined with respect to the unit cell, these concepts are also applicable to the battery comprising a plurality of unit cells. The power is then adapted, and the remaining energy depends on the number of unit cells and their specific arrangement, which may modify Ep.

In the present description, the term “combination” is understood to refer to the mathematical definition allowing the representation of a set of k objects from among n discernible objects numbered from 1 to n and for which the order of the objects is unimportant. In mathematics, the solution to such a problem is given by the formula Cₙ^{k} or

$$( \begin{matrix}n \\ k\end{matrix} ) .$$

The method described below makes it possible to determine a set of characteristic operating points defining the energy behavior of a predetermined battery equipped with a plurality of unit cells.

As illustrated in FIG. 1, the method comprises a step of determining E1 a set of initial operating points associated with a calibration unit cell of the type of those intended to make up said predetermined battery and being representative of the energy behavior of the calibration unit cell. These operating points are referred to as “initial” operating points as they form the basis from which it is possible to determine the characteristic operating points.

The initial operating points may be obtained, for example, in a prior test phase or from a database in which they are held.

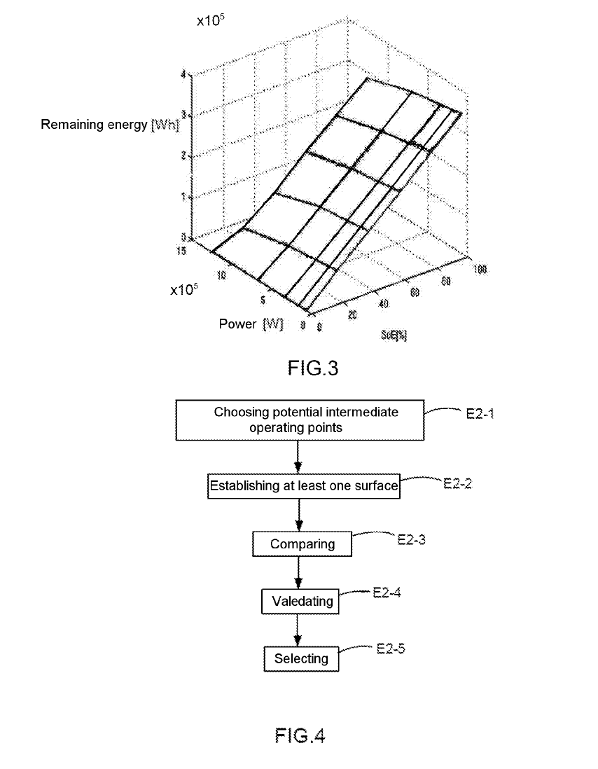

As shown in FIG. 3, according to one particular embodiment, thirty points have been selected.

As unit cells are available in large numbers and are less expensive than a battery, it was possible to use multiple calibration unit cells in order to determine an appropriate number of initial operating points.

This step of determining E1 initial operating points may be carried out on the basis of values that are known and stored, for example, in a table.

If these values are not known, the determination step E1 may comprise a step of characterization through physical and/or electrical tests carried out on at least one calibration unit cell. In fact, the characterization makes it possible to analyze the conformity of a cell and to collect additional information on its properties and characteristics by virtue of a set of physical or electrical tests. A cell is characterized in order to acquire knowledge of its energy behavior and its capability to respond to certain applications, to adapt a tracking algorithm to avoid overcharging, to limit the aging of the cell and, lastly, to develop indicators.

For example, in order to carry out a discharge test of an accumulator at −30° C. starting from an initial charge state of 80%, the procedure for characterizing the unit cell consists of:
charging said unit cell at room temperature in order to reach an SOE of 100%;
allowing to relax for one hour;
discharging, in a controlled manner, 20% of the energy available in the unit cell;
placing the unit cell in a chamber cooled to −30° C.,
waiting for the internal temperature of the unit cell to be equal to −30° C.;
carrying out a residual discharge at a determined power;
measuring the energy available at the end of the residual discharge.

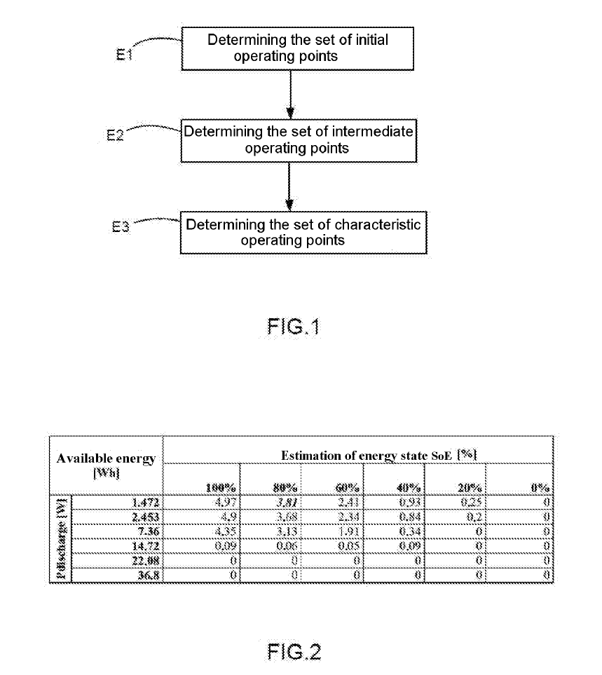

This then makes it possible to deduce an operating point including an energy state of 80%, a power equal to the predetermined power of the residual discharge and a remaining energy equal to the measured remaining energy. This process may be carried out for a plurality of different operating points. This operation is very time consuming, and allows a single characteristic point to be obtained from among all of the points measured in order to establish an energy surface at the temperature of −30° C. (for example). Typically, discharge tests carried out in this way allow a table to be produced that presents the available remaining energy as a function of the desired power and of the energy state SOE; such a table is illustrated in FIG. 2.

The method additionally comprises a step of determining E2 a set of intermediate operating points forming a subset of the set of initial operating points. It is then understood that the number of intermediate operating points is smaller than the number of initial operating points (those shown in FIG. 3).

Lastly, the method comprises a step of determining E3 said set of characteristic operating points through implementing tests carried out on at least one calibration battery representative of said predetermined battery, each test determining a characteristic operating point by using data arising from one of said intermediate operating points. It is then understood that the number of characteristic points is equal to the number of intermediate operating points and therefore smaller than the number of initial operating points.

Once the characteristic operating points have been determined, they could be used in the context of an algorithm for tracking the energy state of any battery of the same type as the predetermined battery.

Preferably, in the context of the determination method, each of the characteristic operating points is defined by at least one value of an energy state of the predetermined battery, one power value of the predetermined battery and one remaining-energy value of the predetermined battery, and each of the initial operating points and each of the intermediate operating points is defined by at least one value of an energy state of the calibration unit cell, one power value of the calibration unit cell and one remaining-energy value of the calibration unit cell. In operation, the charge state of a cell or a battery will potentially vary between 0 and 1 (or 0% and 100%) over a predetermined power range between, for example, Pmin and Pmax, the corresponding remaining energy is associated with the power and energy state values. Of course, when passing from the calibration unit cell to the battery, Pmin and Pmax are adapted according to the arrangement of said unit cells within the battery. Thus, the data (for example the energy state value and/or the power value), arising from one of the intermediate operating points, used to determine a corresponding characteristic operating point are adapted according to the structure of the battery, in particular to the way in which the unit cells of the battery are electrically connected to one another.

Stated otherwise, mathematically, the method may be summarized in the following manner:
E: a finite set of N points Pᵢ belonging to the set of initial operating points numbered from 1 to N such that

E={PᵢεR³, i=1, . . . , N}
Pᵢ: a point of number, and coordinates (xᵢ, yᵢ, zᵢ), where xᵢ is an energy state value, yᵢ is a power value, zᵢ is a remaining-energy value;
(xᵢ, yᵢ): defines a rectangular grid of R², it is understood that this grid is limited due to the calibration unit cell potentially being associated with an energy state varying between 0 and 1 or 0% and 100% and by the power varying within a predetermined range, in particular given by the maker of the unit cell;
E′: a subset of E forming the set of intermediate operating points such that card(E′)=M, whenever M is strictly smaller than N.

Preferably, each implementation of a test consists of carrying out a step of discharging the calibration battery starting from a known energy state and a known discharge power which are determined on the basis of one of the points of the set of determined intermediate operating points in order to obtain, through measurement, a corresponding amount of remaining energy. Consequently, the characteristic operating point is formed through association of the known energy state, the known discharge power and the measured remaining energy. More particularly, a test may reprise the steps of the procedure of characterizing the calibration unit cell, but this time applied to the battery.

Advantageously, the determination method is implemented at various temperatures so as to obtain, for each temperature, a set of associated characteristic operating points. More particularly, a method for characterizing the predetermined battery for a plurality of temperatures comprises, for each temperature, an implementation of the method for determining a set of characteristic operating points defining the energy behavior of the predetermined battery such as described, and a step of associating said temperature with said set of characteristic operating points.

The determined characteristic operating points may then form an energy surface representative of the behavior of the battery. Thus, these points, entered into a table, (for example of the type shown in FIG. 2) may be used in the operation of any battery of the same type as the predetermined battery (i.e. manufactured so as to be identical) in order to acquire real-time knowledge of the energy remaining in the battery, for the purpose of adapting the behavior of a system having to carry out a predetermined function. For example, the system is an electric car and tracking the energy state will allow the autonomy of the electric car to be optimized according to the remaining energy actually available in the battery.

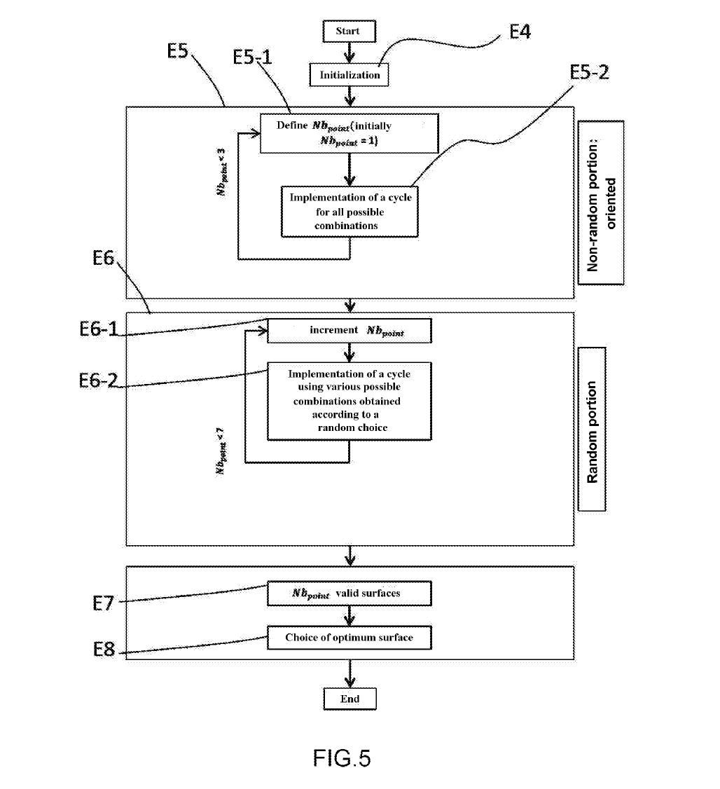

According to one implementation illustrated in FIG. 4, the step of determining E2 the set of intermediate operating points comprises at least one cycle of steps. This cycle of steps comprises a step of choosing E2-1 at least one set of potential intermediate operating points from among the set of initial operating points. These chosen intermediate operating points are referred to as “potential” intermediate operating points since it will be sought to determine whether the latter may be suitable, that is to say whether the latter are sufficiently representative of all of the initial operating points.

The cycle of steps additionally comprises a step of establishing E2-2, for each set of potential intermediate operating points, a corresponding surface, preferably established using Delaunay triangulation. It is then understood that, for each chosen set of potential intermediate operating points, the associated established surface comprises the points of said set of potential intermediate operating points and other computed, or computable, points which are easily found once the established surface is known. In fact, it was possible to determine an equation for said established surface through the interpolation of points, for example, using Delaunay triangulation. Preferably, the established surface is such that all of the points of this surface, whose coordinates in terms of power and energy state are identical to those of the initial operating points, are found (i.e. the remaining energy is determined by interpolation, for example). In fact, an established surface makes it possible to display a set of points each comprising an energy state value of the calibration unit cell, a power value of the calibration unit cell and a remaining-energy value of the calibration unit cell.

Typically, Delaunay triangulation uses a Voronoi diagram. These methods are well known to those skilled in the art and will not be described in detail here. Of course, any type of method allowing the surface, or an equation for the surface, to be established may also be used by those skilled in the art.

The cycle of steps also comprises a step of comparing E2-3 each established surface with all or some of the initial operating points. Preferably, the initial operating points, having served to establish said surface, will not be compared with the latter since they are identical, this allowing, in particular, the processing of the cycle of steps to be sped up.

Lastly, the cycle of steps may comprise a step of validating E2-4 the choice of said at least one set of potential intermediate operating points depending on the result of said comparison. For example, this validation may be acknowledged if all of the initial operating points are sufficiently close to the corresponding operating points of the associated established surface.

When a set of potential intermediate operating points is validated, this means that it may be used in the context of the step of determining E3 the set of characteristic operating points. Stated otherwise, a valid set of potential intermediate operating points may form/constitute the determined set of intermediate operating points.

According to one particular example, translated into mathematical language, the cycle of steps may allow, for a point S of the set of initial operating points with coordinates (x_{SOE}, x_{Pd}, z_{En}) and S′, a point of the set of potential intermediate operating points TD(E′) with coordinates (x_{SOE}, y_{Pd}, z′_{En}) to maximize L=N−M, verifying the following condition:
for any point S belonging to the set of initial points and for any point S′ belonging to TD(E′), ∥z_{En}−z′_{En}∥≦δ is true.

If this condition is satisfied, then the set of potential intermediate operating points is validated.

Physically, L represents the number of tests to be saved. Knowing that N is constant, maximizing L amounts to minimizing M, which represents the number of tests to be decreased. δ represents a level of precision to be maintained, in particular a value representative of a difference between z and z′.

N corresponds to the maximum number of points that form the initial surface. In the present example, N=36 points.

This may be generalized by virtue of the fact that, for each established surface, the comparison step E2-3 comprises, on the one hand, for each initial operating point used in the comparison step E2-3 (that is to say, in other words, for all or some of the initial operating points), forming a pair of points comprising said initial operating point and a point of said established surface for which the energy state values of the calibration unit cell and the power values of the calibration unit cell are identical to those of said initial operating point and comprises, on the other hand, for each pair of points, determining a difference between the remaining-energy values of said initial operating point and of said point of said established surface. Next, the validation step E2-4 comprises validating said at least one chosen set of potential intermediate operating points if, for each pair of points, said difference, or a value representative of the difference, is lower than a threshold (this threshold corresponding to δ in the example above) then forming a first optimization condition.

The value representing the difference may, for example, be a percentage, the threshold is then typically lower than 3% such that the remaining-energy value of said point of said established surface is between −3% and +3% with respect to the value of the corresponding initial operating point.

It is understood from the above that it is possible to encounter the following situation:
multiple sets of potential intermediate operating points from among the set of initial operating points have been chosen during the implementation of the choice step E2-1;
multiple sets of potential intermediate operating points are validated during the implementation of said validation step E2-4.

This results in multiple validated sets of intermediate operating points which could be used in order to determine the characteristic operating points. However, as it is sought to minimize the points to be tested on the battery, it will be sought to select a single validated set of intermediate operating points. This selected set is, preferably, the best adapted and the most representative of the behavior of the calibration unit cell.

Within this context, the method may comprise a step of selecting E2-5 a single set of intermediate operating points from among said multiple validated sets of intermediate operating points. Consequently, this selected set will form the determined set of intermediate operating points. According to one particular implementation of the selection step E2-5, the latter comprises establishing, for each of the established surfaces associated with the validated sets of potential intermediate operating points, an average value of the difference determined between the remaining-energy values of the points of each pair associated with said established surface, the selected set of intermediate operating points corresponding to that associated with the established surface for which the value of the average is lowest.

Stated otherwise, this new condition allows an optimum solution to be chosen from among the set of valid solutions (surfaces), that is to say, mathematically speaking, for any operating point Pᵢ (x_{SOEi}, y_{Pdi}, z_{Eni}) belonging to the set of initial points, and for any operating point of the established surface with coordinates S′(x_{SOEi}, y_{Pdi}, Z_{En i}′) which is associated with a validated set of intermediate operating points, Moy (∥zᵢ−zᵢ′∥) is true: the average of

$$( ‖ {z}_{i} - {z}_{i}^{′} ‖ ) = ( 1 / N ) * {\sum }_{i = 1}^{N} ‖ {z}_{i} - {z}_{i}^{′} ‖ .$$

The use of an average value may also be advantageous in the context of validating E2-4 a set of potential intermediate points. Specifically, the validation step E2-4 may comprise a first phase in which it is verified whether, for each pair of points, said difference, or a value representative of the difference, is lower than the associated threshold (δ in the example above) and a second phase in which the validation of said set of potential intermediate points is confirmed only if the average value (or a value representative of this average value) of the determined difference between the remaining-energy values of the points of each pair associated with said established surface is lower than a corresponding threshold (it is then possible to have Moy (∥zᵢ−zᵢ′∥)≦α≦δ, where α is a positive real integer forming said corresponding threshold) then forming a second optimization condition.

α is defined so as to maintain a similarity between the initial and final (optimum) surface. The right choice of a makes the (optimum) surface planar and will avoid, locally, the presence of small bumps.

According to one particular implementation of the method for determining the set of characteristic operating points, illustrated in FIG. 5, the latter comprises a first, initialization step E4 in which four end operating points chosen from among the set of initial operating points are fixed, the remaining initial operating points forming a set of internal operating points.

The end operating points are formed by mesh points which “frame” the internal operating points. The four end points are advantageously formed by the following points: (0, Pmin, 0), (0, Pmax, 0), (1, Pmin, z1) and (1, Pmax, z2), where z1 and z2 are the associated remaining-energy values having been determined, in particular, during the characterization of the calibration unit cell.

Additionally, in said particular implementation of the method, the latter comprises a second step E5 comprising a step of defining E5-1 a variable Nbₚₒᵢₙₜ representative of a number of operating points of the set of internal operating points to be used. Furthermore, the second step comprises a step E5-2 of implementing the cycle of steps described above (steps E2-1 to E2-4 or E2-5 of FIG. 2). Preferably, the cycle of steps is such that all possible combinations of Nbₚₒᵢₙₜ points from among the total number of points of the set of internal operating points are determined, and the choice step (E2-1) is such that each chosen set of potential intermediate operating points comprises (preferably only) the four fixed end points and one of said possible combinations.

Preferably, in a first iteration of the second step E5, the value of Nbₚₒᵢₙₜ is 1 (stated otherwise, the step of defining E5-1 Nbₚₒᵢₙₜ has set Nbₚₒᵢₙₜ to 1). If no set of potential intermediate points is validated during the implementation of the cycle of steps associated with the first iteration of the second step, the method then comprises a second iteration of the second step E5 for which the value of Nbₚₒᵢₙₜ is 2 (on exiting step E5-2, step E5-1 is returned to in which the variable Nbₚₒᵢₙₜ is incremented in increments of 1). In this specific case, a step (not shown) subsequent to step E5-2 may make it possible to verify whether no set has been validated and if this is the case, the method returns to step E5-1, in particular when Nbₚₒᵢₙₜ is strictly smaller than 3, where Nbₚₒᵢₙₜ is incremented.

Preferably, all of the chosen sets of potential intermediate points form, in this instance, a set of established corresponding surfaces which may or may not have to be validated.

For Nbₚₒᵢₙₜ equal to 1 or 2, the number of sets of potential intermediate operating points is such that a “brute force” attack, by testing all of the associated established surfaces, is achievable within a reasonable time frame using the computing means at the disposal of those skilled in the art.

If a chosen set of potential operating points is validated, then the step of determining the set of intermediate operating points may be halted and the determined set of intermediate operating points is formed/constituted by the validated set of potential intermediate operating points.

Mathematically, this second step E5 may be qualified as an oriented non-random portion.

Beyond Nbₚₒᵢₙₜ=2, it is preferable to optimize the execution of the method in order to decrease the time required to find one or more solutions to the optimization problem. Within this context, it is possible to implement a random choice of points of sets of points to be tested (referred to as the random portion in FIG. 5). In particular, if, after j iterations of the second step E5, j preferably being equal to 2, no set of potential intermediate operating points has been validated, the method comprises a third step E6 comprising the following steps:
incrementing Nbₚₒᵢₙₜ (preferably, after the first increment of this step E6, Nbₚₒᵢₙₜ is equal to 3) and randomly forming sets of Nbₚₒᵢₙₜ points (E6-1), preferably distinct, chosen from among the points of the set of internal operating points until the number of sets of Nbₚₒᵢₙₜ points is equal to a predetermined threshold that is lower than the number of possible combinations of Nbₚₒᵢₙₜ points from among the total number of points of the set of internal operating points;
determining a plurality of surfaces, in particular from the Delaunay triangulation, each of the surfaces of the plurality of surfaces being defined on the basis of the four fixed end points and of one of the randomly formed sets of Nbₚₒᵢₙₜ points (in other words, these points are part of said surface);
comparing each of the surfaces of the plurality of surfaces with the operating points of the set of initial points;
defining the points having been used to define a surface of the plurality of surfaces as a set of validated intermediate operating points if said step of comparing said surface satisfies an optimization condition, or else carrying out a new third step, preferably while Nbₚₒᵢₙₜ is smaller than or equal to 6.

The steps of determining the plurality of surfaces, of comparing and of defining the points of step E6 are shown within step E6-2 of FIG. 5.

The predetermined threshold that is lower than the number of possible combinations of Nbₚₒᵢₙₜ points from among the total number of points of the set of internal operating points allows the number of established surfaces to be limited. This threshold may depend on the available computing power, typically it may be lower than 15 000.

The optimization condition of the step of defining the points of step E6 may be identical to the first optimization condition, moreover, the second optimization condition may also be applied. It is then understood that all of the above relating to the step of validating E2-4 the cycle of steps is advantageously applicable in the step of defining the points of step E6 for the purpose of validating or not validating the points having been used to define a surface of the plurality of surfaces as validated intermediate operating points.

Furthermore, it is possible for the second step E5, or for the third step E6, to allow multiple validated sets of intermediate operating points to be found. Within this context, the selection step E2-5 described above may also be applied in the context of the second step E5 or the third step E6 for the purpose of selecting only one validated set of intermediate operating points.

In general, at least one set of potential intermediate operating points is found before Nbₚₒᵢₙₜ is equal to 6 or once Nbₚₒᵢₙₜ is equal to 6. This limit thus allows the method to be halted and a problem to be signaled to an operator if no solution is found at that time.

According to one variant that can be seen in FIG. 5, for each Nbₚₒᵢₙₜ value, an established surface is extracted. When, for one value of Nbₚₒᵢₙₜ, multiple possible surfaces are obtained (in particular for values of Nbₚₒᵢₙₜ above 2), only the most adequate surface for said value of Nbₚₒᵢₙₜ is retained (in particular by implementing step E2-5 described above). In this variant, the Nbₚₒᵢₙₜ value preferably remains strictly lower than 7. After implementing step E6, Nbₚₒᵢₙₜ valid surfaces are then obtained (step 7) and it is then necessary to choose, at the end of the method, the optimum one (step E8) out of the Nbₚₒᵢₙₜ valid surfaces (for example by implementing step E2-5 described above). In this variant, step E5 is preferably implemented twice and step E6 is implemented four times.

In the case in which it is sought to determine the set of intermediate operating points as quickly as possible, the cycle of steps is carried out such that, after establishing a surface, the associated comparison step is implemented before establishing any other surface, for the purpose of validating, or not validating, the potential intermediate operating points associated with said established surface. Thus, in the case in which the potential intermediate operating points associated with said established surface are validated, the step of determining the intermediate operating points is halted and the validated set of potential intermediate operating points is used in the step of determining the set of characteristic operating points as a set of determined intermediate operating points.

Alternatively, one iteration of said cycle of steps comprises choosing a single set of potential intermediate operating points. Thus, if, in this iteration, the choice is validated, the step of determining the intermediate operating points is terminated, otherwise a new iteration of the cycle is carried out with a new single chosen set of potential intermediate operating points.

The object of the preceding two paragraphs is also valid in the context of implementing the second step or the third step, even if the corresponding predetermined threshold has not yet been reached.

Stated otherwise, it is understood, in this instance, that as soon as a set of potential intermediate operating points is chosen, it is sought to determine whether it is valid or not before choosing another set of potential intermediate operating points. As soon as a set of potential intermediate operating points is validated, the step of determining the set of intermediate operating points is halted and the determined set of intermediate operating points corresponds to the validated set of potential intermediate operating points.

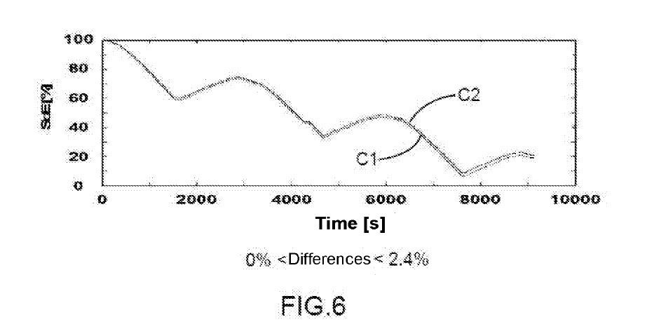

The present determination method has been used in order to characterize a battery, one unit cell of which is usually characterized by 36 initial operating points at a given temperature (FIG. 2). Said method has been able to feature fewer than eight operating points of the set of relevant initial points for determining the set of characteristic operating points. Tests have therefore been carried out in order to characterize the type of battery with the eight featured points and with the 36 initial points in order to obtain two distinct maps that are representative of the energy behavior over eight points and over 36 points. Next, the obtained maps have been used in the context of a simulation on a first battery and on a second battery, respectively, according to one and the same algorithm for tracking the energy state for one and the same behavior in terms of electrical consumption and under identical temperature conditions. FIG. 6 illustrates two representative usage curves: curve C1 corresponds to tracking using the map with 36 points and curve C2 corresponds to tracking using the map with eight points. It can be seen that the final difference between the simulations is relatively small (less than 2.4%) and is fully acceptable considering the time saved and the cost associated with characterizing the battery.

A device may comprise a computer and means for implementing the method for determining the set of characteristic operating points and/or means for implementing the method for characterizing a predetermined battery equipped with a plurality of unit cells for a plurality of temperatures. In particular, the device may comprise as many elements as there are steps in the associated method, it is then understood that each element is configured so as to allow a corresponding step of the associated method to be implemented.

1. A method for determining a set of characteristic operating points defining the energy behavior of a predetermined battery equipped with a plurality of unit cells, the method comprising:
determining a set of initial operating points associated with a calibration unit cell of the type of those intended to make up the predetermined battery and being representative of the energy behavior of the calibration unit cell;
determining a set of intermediate operating points forming a subset of the set of initial operating points;
determining the set of characteristic operating points through implementing tests carried out on at least one calibration battery representative of the predetermined battery, each test determining a characteristic operating point by using data arising from one of the intermediate operating points.

2. The method as claimed in claim 1, wherein each of the characteristic operating points is defined by at least one value of an energy state of the predetermined battery, one power value of the predetermined battery and one remaining-energy value of the predetermined battery, and wherein each of the initial operating points and each of the intermediate operating points is defined by at least one value of an energy state of the calibration unit cell, one power value of the calibration unit cell and one remaining-energy value of the calibration unit cell.

3. The method as claimed in claim 2, wherein the determining of the set of intermediate operating points comprises at least one cycle of the following actions:
choosing at least one set of potential intermediate operating points from among the set of initial operating points;
establishing, for each set of potential intermediate operating points, a corresponding surface;
comparing each established surface with all or some of the initial operating points;
validating the choice of the at least one set of potential intermediate operating points depending on the result of the comparing.

4. The method as claimed in claim 3, wherein, for each established surface:
the comparing comprises (i) for each initial operating point used in the comparing, forming a pair of points comprising the initial operating point and a point of the established surface for which the energy state values of the calibration unit cell and the power values of the calibration unit cell are identical to those of the initial operating point, and (ii) for each pair of points, determining a difference between the remaining-energy values of the initial operating point and of the point of the established surface;
the validating comprises validating the at least one chosen set of potential intermediate operating points if, for each pair of points, the difference, or a value representative of the difference, is lower than a threshold.

5. The method as claimed in claim 4, comprising:
choosing multiple sets of potential intermediate operating points from among the set of initial operating points;
during the implementing of the validating, validating multiple sets of potential intermediate operating points; and
selecting a single set of intermediate operating points from among the multiple validated sets of intermediate operating points.

6. The method as claimed in claim 5, wherein the selecting comprises establishing, for each of the established surfaces associated with the validated sets of potential intermediate operating points, an average value of the difference determined between the remaining-energy values of the points of each pair associated with the established surface, the selected set of intermediate operating points corresponding to the set of intermediate operating points associated with the established surface for which the value of the average is lowest.

7. The method as claimed in claim 3, comprising, a first, initializing action wherein, during the initializing, four end operating points chosen from among the set of initial operating points are fixed, the remaining initial operating points forming a set of internal operating points, and a second action comprising, performing the following:
defining a variable Nbₚₒᵢₙₜ representative of a number of operating points of the set of internal operating points to be used;
implementing the cycle of actions in which:
all possible combinations of Nbₚₒᵢₙₜ points from among the total number of points of the set of internal operating points are determined;
the choosing is performed so that each chosen set of potential intermediate operating points comprises the four fixed end points and one of the possible combinations.

8. The method as claimed in claim 7, comprising a first iteration of the second action, for which the value of Nbₚₒᵢₙₜ is 1, and a second iteration of the second action, for which the value of Nbₚₒᵢₙₜ is 2, if no set of potential intermediate points is validated during the implementation of the cycle of actions associated with the first iteration of the second action.

9. The method as claimed in claim 8, wherein, if, after j iterations of the second actions no set of potential intermediate operating points has been validated, the method comprises a third action comprising:
incrementing Nbₚₒᵢₙₜ and randomly forming sets of Nbₚₒᵢₙₜ points, chosen from among the points of the set of internal operating points until the number of sets of Nbₚₒᵢₙₜ points is equal to a predetermined threshold that is lower than the number of possible combinations of Nbₚₒᵢₙₜ points from among the total number of points of the set of internal operating points;
determining a plurality of surfaces, each of the surfaces of the plurality of surfaces being defined on the basis of the four fixed end points and of one of the randomly formed sets of Nbₚₒᵢₙₜ points;
comparing each of the surfaces of the plurality of surfaces with the operating points of the set of initial points;
defining the points having been used to define a surface of the plurality of surfaces as a validated set of intermediate operating points if the comparing of the surface satisfies an optimization condition, or else carrying out a new third action.

10. The method as claimed in claim 1, wherein each implementation of a test consists of carrying out discharging the calibration battery starting from a known energy state and a known discharge power which are determined on the basis of one of the points of the set of determined intermediate points, of measuring a corresponding amount of remaining energy, and of forming the characteristic operating point through association of the known energy state, the known discharge power and the measured remaining energy.

11. A method for characterizing a predetermined battery equipped with a plurality of unit cells for a plurality of temperatures, the method comprising, for each temperature, implementing the method for determining a set of characteristic operating points defining the energy behavior of the predetermined battery as claimed in claim 1, and associating the temperature with the set of characteristic operating points.

12. The method as claimed in claim 3, wherein the corresponding surface for each set of potential intermediate operating points is established using Delaunay triangulation.

13. The method as claimed in claim 9, wherein, j is equal to 2.

14. The method as claimed in claim 9, wherein the plurality of surfaces are determined from the Delaunay triangulation.

15. The method as claimed in claim 9, wherein the new third action is carried out while Nbₚₒᵢₙₜ is smaller than or equal to 6.

16. The method as claimed in claim 1, wherein the determining of the set of intermediate operating points comprises at least one cycle of the following actions:
choosing at least one set of potential intermediate operating points from among the set of initial operating points;
establishing, for each set of potential intermediate operating points, a corresponding surface;
comparing each established surface with all or some of the initial operating points;
validating the choice of the at least one set of potential intermediate operating points depending on the result of the comparing.

17. The method as claimed in claim 16, wherein, for each established surface:
the comparing comprises (i) for each initial operating point used in the comparing, forming a pair of points comprising the initial operating point and a point of the established surface for which the energy state values of the calibration unit cell and the power values of the calibration unit cell are identical to those of the initial operating point, and (ii) for each pair of points, determining a difference between the remaining-energy values of the initial operating point and of the point of the established surface;
the validating comprises validating the at least one chosen set of potential intermediate operating points if, for each pair of points, the difference, or a value representative of the difference, is lower than a threshold.

18. The method as claimed in claim 16, comprising:
choosing multiple sets of potential intermediate operating points from among the set of initial operating points;
during the implementing of the validating, validating multiple sets of potential intermediate operating points; and
selecting a single set of intermediate operating points from among the multiple validated sets of intermediate operating points.

19. The method as claimed in claim 17, comprising:
choosing multiple sets of potential intermediate operating points from among the set of initial operating points;
during the implementing of the validating, validating multiple sets of potential intermediate operating points; and
selecting a single set of intermediate operating points from among the multiple validated sets of intermediate operating points.

20. The method as claimed in claim 3, comprising:
choosing multiple sets of potential intermediate operating points from among the set of initial operating points;
during the implementing of the validating, validating multiple sets of potential intermediate operating points; and
selecting a single set of intermediate operating points from among the multiple validated sets of intermediate operating points.
